(19) United States
(12) Patent Application Publication
(10) Pub. No.: US 2026/0247533 A1
(43) Pub. Date: Aug. 20, 2026

(54) ELECTRONIC DEVICE

(71) Applicant: Advanced Semiconductor Engineering, Inc., Kaohsiung (TW)

(72) Inventors: Cheng Ruei Hung, Kaohsiung (TW); Chien-Yuan Tseng, Kaohsiung (TW); Zhi-Yuan LIN, Kaohsiung (TW); Shao Chieh Huang, Kaohsiung (TW)

(73) Assignee: Advanced Semiconductor Engineering, Inc., Kaohsiung (TW)

(21) Appl. No.: 19/054,717

(22) Filed: Feb. 14, 2025

Related U.S. Application Data
(60) Provisional application No. 63/733,964, filed on Dec. 13, 2024.

(51) Int. Cl. H05K 1/14; H05K 1/18

(52) U.S. Cl. CPC H05K 1/145; H05K 1/181; H05K 1/185; H05K 2201/042

(57) ABSTRACT

An electronic device is provided. The electronic device includes a first carrier, a second carrier, a first support, and a plurality of voltage regulating components. The second carrier is stacked over the first carrier. The first support is disposed between the first carrier and the second carrier and is at a central region of the first carrier. The voltage regulating components are disposed between the first carrier and the second carrier. At least one of the voltage regulating components is outside of the central region of the first carrier.

### BACKGROUND

### 1. Technical Field

The present disclosure relates generally to an electronic device.

### 2. Description of the Related Art

Three-dimensional system-in-package (3D SIP) modules may be applied in AI (artificial intelligence) training data centers. By vertically integrating integrated circuit (IC) modules and capacitors, signal transmission paths and heat dissipation paths are shortened. Because of the increased demand for electrical performance of 3D SIP modules, it is necessary to arrange high-performance IC modules within the modules. Therefore, this structure needs to be modified to facilitate the arrangement of more efficient passive components (e.g., capacitors) and to increase the number of the passive components.

### SUMMARY

In one or more arrangements, an electronic device includes a first carrier, a second carrier, a first support, and a plurality of voltage regulating components. The second carrier is stacked over the first carrier. The first support is disposed between the first carrier and the second carrier and is at a central region of the first carrier. The voltage regulating components are disposed between the first carrier and the second carrier. At least one of the voltage regulating components is outside of the central region of the first carrier.

In one or more arrangements, an electronic device includes a first carrier, a second carrier, a plurality of conductive elements, and at least one support. The second carrier is stacked over the first carrier. The conductive elements are configured to transmit a power signal between the first carrier and the second carrier. At least one support is disposed between the first carrier and the second carrier and is configured to withstand a force on the conductive elements.

In one or more arrangements, an electronic device includes a first carrier, a second carrier, and a plurality of conductive elements. The second carrier is stacked over the first carrier. The conductive elements are disposed between the first carrier and the second carrier. The conductive elements include a first conductive element configured to transmit a power signal and a second conductive element including voids.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of an electronic device in accordance with some arrangements of the present disclosure.

FIG. 1B is a top view of an electronic device in accordance with some arrangements of the present disclosure.

FIG. 1C is a top view of an electronic device in accordance with some arrangements of the present disclosure.

FIG. 1D is a top view of an electronic device in accordance with some arrangements of the present disclosure.

FIG. 1E is a top view of an electronic device in accordance with some arrangements of the present disclosure.

FIG. 2A is a cross-section of an electronic device in accordance with some arrangements of the present disclosure.

FIG. 2B is a top view of an electronic device in accordance with some arrangements of the present disclosure.

FIG. 2C is a top view of an electronic device in accordance with some arrangements of the present disclosure.

FIG. 2D is a cross-section of an electronic device in accordance with some arrangements of the present disclosure.

FIG. 3A is a cross-section of an electronic device in accordance with some arrangements of the present disclosure.

FIG. 3B is a cross-section of an electronic device in accordance with some arrangements of the present disclosure.

FIG. 3C is a cross-section of an electronic device in accordance with some arrangements of the present disclosure.

FIG. 4A is a cross-section of an electronic device in accordance with some arrangements of the present disclosure.

FIG. 4B is a cross-section of an electronic device in accordance with some arrangements of the present disclosure.

FIG. 4C is a cross-section of an electronic device in accordance with some arrangements of the present disclosure.

FIG. 4D is a cross-section of a portion of an electronic device in accordance with some arrangements of the present disclosure.

FIG. 4E is a cross-section of a portion of an electronic device in accordance with some arrangements of the present disclosure.

FIG. 4F is a cross-section of a portion of an electronic device in accordance with some arrangements of the present disclosure.

FIG. 4G is a cross-section of a portion of an electronic device in accordance with some arrangements of the present disclosure.

FIG. 4H is a cross-section of a portion of an electronic device in accordance with some arrangements of the present disclosure.

FIG. 5A, FIG. 5B, FIG. 5C, FIG. 5D, FIG. 5E, FIG. 5F, and FIG. 5G illustrate various stages of an exemplary method for manufacturing an electronic device in accordance with some embodiments of the present disclosure.

FIG. 6A and FIG. 6B illustrate various stages of an exemplary method for manufacturing an electronic device in accordance with some embodiments of the present disclosure.

FIG. 7A, FIG. 7B, FIG. 7C, FIG. 7D, FIG. 7E, FIG. 7F, FIG. 7G, and FIG. 7H illustrate various stages of an exemplary method for manufacturing an electronic device in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

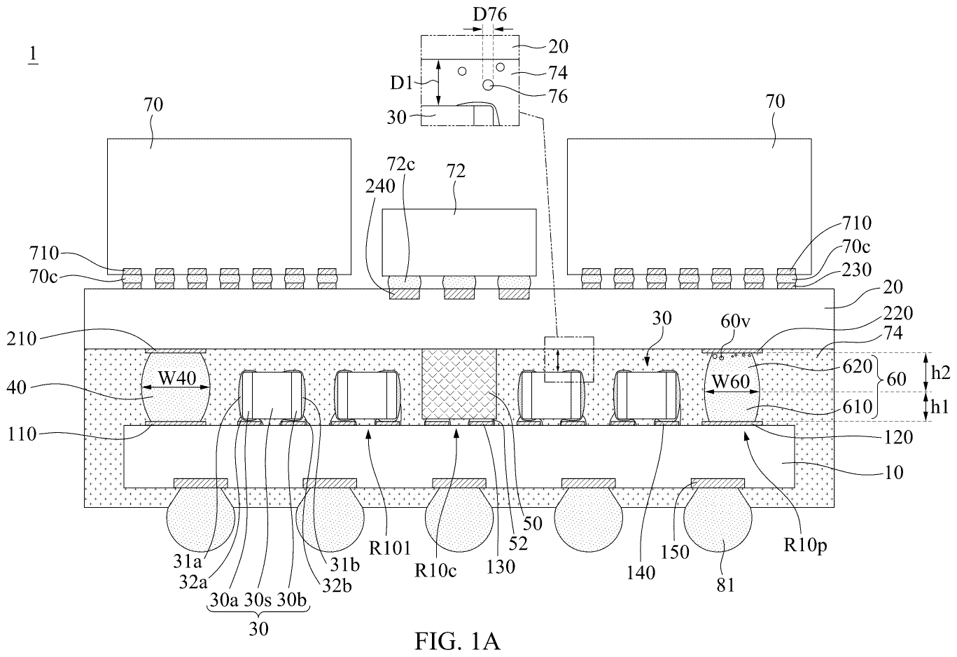

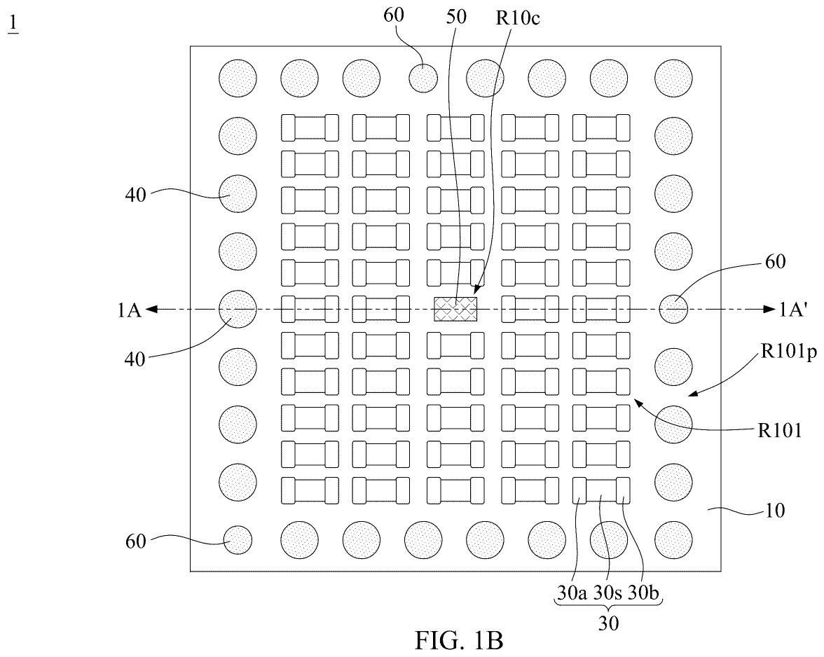

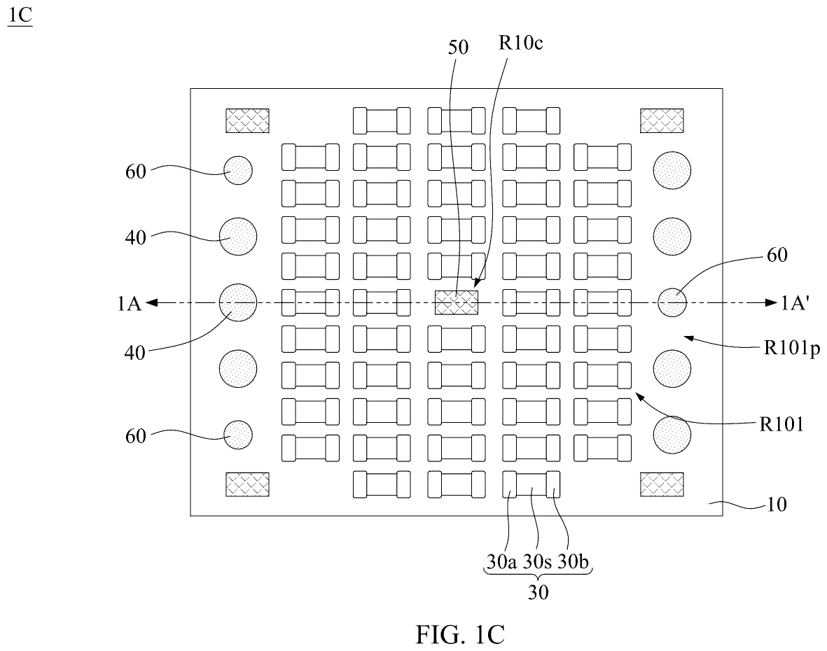

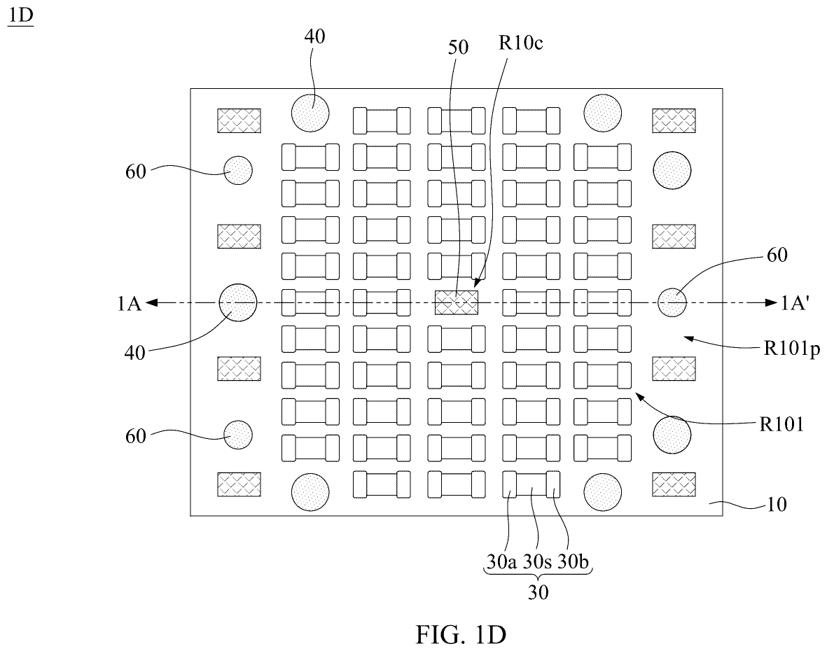

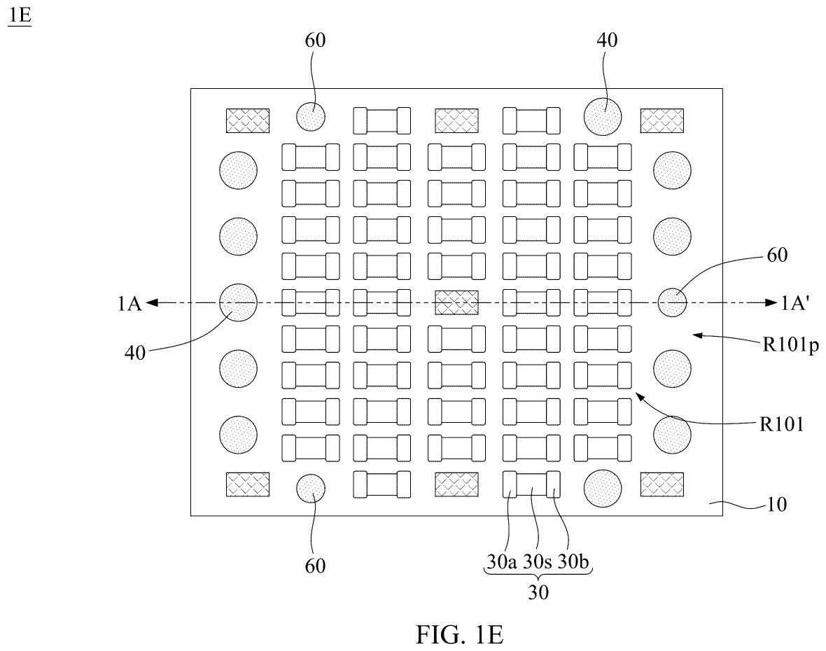

FIG. 1A is a cross-section of an electronic device 1 in accordance with some arrangements of the present disclosure. FIG. 1B is a top view of an electronic device 1 in accordance with some arrangements of the present disclosure. In some arrangements, FIG. 1A is a cross-section along a line 1A-1A′ in FIG. 1B. Please be noted that some components/elements are omitted in FIG. 1B for clarity. The electronic device 1 may include carriers 10 and 20, electronic components 30 and 70, solder elements 31a, 31b, 32a, 32b, and 52, conductive elements 40, supports 50 and 60, a connector 72, an encapsulant 74, and electrical contacts 81. In some arrangements, the electronic device 1 may be or include a system-in-package (SiP). In some arrangements, the electronic device 1 may be or include an IC module.

The carrier 10 may include, for example, a printed circuit board, such as a paper-based copper foil laminate, a composite copper foil laminate, or a polymer-impregnated glass-fiber-based copper foil laminate. The carrier 10 may include an interconnection structure, such as a plurality of conductive traces and/or a plurality of conductive vias. In some arrangements, the carrier 10 includes a ceramic material, a metal plate, an organic substrate, or a leadframe. In some arrangements, the carrier 10 may include a two-layer substrate which includes a core layer and a conductive material and/or structure disposed on an upper surface and a bottom surface of the carrier 10. The conductive material and/or structure may include a plurality of conductive traces. In some arrangements, the carrier 10 includes pads 110, 120, 130, 140, and 150 (or conductive pads) exposed from surfaces of the carrier 10. The carrier 10 may include a central region R10c, a peripheral region R10p, and a region R101. The region R101 may be beside the central region R10c. In some arrangements, the region R101 is between the central region R10c and the peripheral region R10p.

The carrier 20 may be stacked over the carrier 10. The carrier 20 may include, for example, a printed circuit board, such as a paper-based copper foil laminate, a composite copper foil laminate, or a polymer-impregnated glass-fiber-based copper foil laminate. The carrier 20 may include an interconnection structure, such as a plurality of conductive traces and/or a plurality of conductive vias. In some arrangements, the carrier 20 includes a ceramic material, a metal plate, an organic substrate, or a leadframe. In some arrangements, the carrier 20 may include a two-layer substrate which includes a core layer and a conductive material and/or structure disposed on an upper surface and a bottom surface of the carrier 20. The conductive material and/or structure may include a plurality of conductive traces. In some arrangements, the carrier 20 includes pads 210, 220, 230, and 240 (or conductive pads) exposed from surfaces of the carrier 20.

The electronic components 30 may be disposed between the carrier 10 and the carrier 20. In some arrangements, at least one of the electronic components 30 is disposed at the region R101 beside the central region R10c of the carrier 10. In some arrangements, the electronic components 30 are arranged in a single layer between the carrier 10 and the carrier 20. The electronic components 30 may be or include voltage regulating components. In some arrangements, the electronic components 30 include surface mount devices (SMDs). In some arrangements, the electronic components 30 include passive components. In some arrangements, the electronic components 30 are connected to the carrier 10 through surface mount connection or by a surface mount technology (SMT) process. In some arrangements, the electronic components 30 include capacitors. In some arrangements, the electronic component 30 includes a base layer 30s and electrodes 30a and 30b (also referred to as “contacts”). The electrode 30a may be opposite to the electrode 30b. The electrodes 30a and 30b extend between the carrier 10 and the carrier 20. The base layer 30s may be an insulating layer, e.g., a ceramic layer.

In some arrangements, each of the electronic components 30 is electrically connected to the carrier 10 through the solder elements 31a, 31b, 32a, and 32b. In some arrangements, the solder element 31a is on the electrode 30a, and the solder element 31b is on the electrode 30b. In some arrangements, the solder elements 31a and 31b connect the electronic components 30 (or the voltage regulating components) to the pads 140. In some arrangements, the solder element 32a is disposed between the pad 140 and the solder element 31a, and the solder element 32b is disposed between the pad 140 and the solder element 31b. In some arrangements, the electrode 30a is electrically connected to the pad 140 through the solder elements 31a and 32a, and the electrode 30b is electrically connected to the pad 140 through the solder elements 31b and 32b.

The conductive elements 40 may connect the carrier 10 to the carrier 20 and configured to transmit a power signal. In some arrangements, the conductive element 40 is configured to transmit a power signal between the carrier 10 and the carrier 20. In some arrangements, the conductive element 40 electrically connects the pad 210 of the carrier 20 to the pad 110 of the carrier 10. In some arrangements, at least one of the conductive elements 40 is disposed at a region beside the region R101 of the carrier 10. In some arrangements, at least one of the conductive elements 40 is disposed at the peripheral region R10p of the carrier 10. In some arrangements, the conductive elements 40 are or include reflowable elements. In some arrangements, the conductive elements 40 include at least a soldering material. In some arrangements, the conductive elements 40 are or include solder elements, e.g., controlled collapse chip connection (C4) bumps, a ball grid array (BGA), or a land grid array (LGA).

The support 50 may be disposed between the carrier 10 and the carrier 20. In some arrangements, the support 50 is at the central region R10c of the carrier 10. In some arrangements, the support 50 is disposed closer to the carrier 20 than the electronic components 30 (or the voltage regulating components) are. In some arrangements, a height of the support 50 is greater than a height of the electronic components 30 (or the voltage regulating components). In some arrangements, the support 50 is disposed between the carrier 10 and the carrier 20 and configured to withstand a force by a mold on the conductive elements 40. In some arrangements, a rigidity (or a hardness) of the support 50 is greater than a rigidity (or a hardness) of the conductive elements 40. In some arrangements, the support 50 has a Brinell hardness (HB) of at least 150, e.g., 150-200. In some arrangements, the support 50 has a hardness of at least 1000 HV in Vickers hardness, e.g., 1200-1800. In some arrangements, the support 50 includes or is formed of a metal material (e.g., copper or a Cu—Ni alloy), a ceramic material, or a plastic material having a rigidity (or a hardness) greater than that of the conductive elements 40 (e.g., the solder elements). In some arrangements, the support 50 is or includes a conductive element. In some arrangements, the support 50 is free of a solder material. In some arrangements, an aspect ratio of the support 50 is greater than an aspect ratio of a solder ball (e.g., the conductive element 40). In some arrangements, the aspect ratio of the support 50 is equal to or greater than 0, 0.1, 0.3, or 0.5. In some arrangements, the aspect ratio of the support 60 is equal to or less than about 2.5, 2.2, or 2.

In some arrangements, the support 50 is connected to the carrier 10 through surface mount connection or by a SMT process. In some arrangements, the solder element 52 connects the support 50 to the pads 130 of the carrier 10. In some arrangements, the solder element 52 includes two portions that are spaced apart from each other and contacting two pads 130, respectively. In some arrangements, the pads 130 are conductive pads. In some arrangements, the pads 130 are dummy pads without electrical connection functions. In some arrangements, the support 50 is configured to be free of electrical connection functions. In some arrangements, the support 50 is configured to provide electrical connection functions. In some arrangements, the support 50 is configured to transmit an electrical signal (e.g., a power signal, a control signal, or other electrical signals) through the pad 130. In some arrangements, a distance between the support 50 and the carrier 20 is less than a distance D1 between the electronic components 30 and the carrier 20. For example, the support 50 may contact the carrier 20 with substantially no distance between the support 50 and the carrier 20.

The supports 60 may be disposed between the carrier 10 and the carrier 20. In some arrangements, the supports 60 connect the pads 220 of the carrier 20 to the pads 120 of the carrier 10. In some arrangements, the supports 60 are disposed at the peripheral region R10p of the carrier 10. In some arrangements, the pads 120 and 220 are conductive pads. In some arrangements, the pads 120 and 220 are dummy pads without electrical connection functions. In some arrangements, the support 60 is configured to be free of electrical connection functions. In some arrangements, the support 60 is configured to provide electrical connection functions. In some arrangements, the support 60 is configured to transmit an electrical signal (e.g., a power signal, a control signal, or other electrical signals) through the pads 120 and 220. In some arrangements, the supports 50 and 60 are all closer to the carrier 20 than the electronic components 30 (or the voltage regulating components) are. In some arrangements, the supports 60 include voids 60v. In some arrangements, the voids 60v are closer to the carrier 20 than to the carrier 10. In some arrangements, an aspect ratio of the support 60 is greater than an aspect ratio of a solder ball (e.g., the conductive element 40). In some arrangements, the aspect ratio of the support 60 is equal to or greater than 0, 0.1, 0.3, or 0.5. In some arrangements, the aspect ratio of the support 60 is equal to or less than about 1.8, 1.6, or 1.4.

In some arrangements, at least one of the supports 60 includes portions 610 and 620 connected to each other and tapering toward opposite directions. In some arrangements, the portion 610 tapers toward the carrier 10, the portion 620 tapers toward the carrier 20, and a thickness h1 of the portion 610 is less than a thickness h2 of the portion 620. In some arrangements, the supports 60 include at least a soldering material. In some arrangements, the supports 60 are or include conductive elements. In some arrangements, a height of the support 60 is substantially equal to a height of the conductive elements 40, and a width W60 of the support 60 is less than a width W40 of the conductive elements 40. In some arrangements, the width W40 is the maximum width of the conductive element 40 and is located substantially at the midpoint of its height, and the width W60 is the maximum width of the support 60 and is not located at the midpoint of its height. In some arrangements, the maximum width W60 of the support 60 is closer to the carrier 10 than to the carrier 20. In some arrangements, the support 60 and the support 50 include different materials. In some arrangements, a rigidity (or a hardness) of the support 50 is greater than a rigidity (or a hardness) of the support 60.

Referring to FIG. 1B, in some arrangements, the supports 50 and 60 are disposed between the conductive elements 40. In some arrangements, the electronic components 30 (or the voltage regulating components) are disposed between the support 50 and the supports 60 from a top view perspective. In some arrangements, the electronic components 30 (or the voltage regulating components) are disposed between the support 50 and the conductive elements 40 from a top view perspective.

The electronic components 70 may be disposed over the carrier 20. In some arrangements, the electronic components 70 are electrically connected to the carrier 20. In some arrangements, pads 710 (or conductive pads) of the electronic components 70 are electrically connected to the pads 230 of the carrier 20 through connection elements 70c. The connection elements 70c may be or include conductive bumps or solder bumps. The electronic components 70 may be or include power modules.

The connector 72 may be disposed over the carrier 20. In some arrangements, the connector 72 is electrically connected to the carrier 20. In some arrangements, the connector 72 is electrically connected to the pads 240 of the carrier 20 through connection elements 72c. The connection elements 72c may be or include conductive bumps or solder bumps.

The encapsulant 74 may encapsulate the electronic components 30 (or the voltage regulating components). In some arrangements, the encapsulant 74 encapsulates the carrier 10, the electronic components 30, the conductive elements 40, and the supports 50 and 60. In some arrangements, the encapsulant 74 includes a plurality of fillers 76. The encapsulant 74 may be or include an encapsulant material. The encapsulant material may include an epoxy resin having the fillers 76 dispersed therein, a molding compound (e.g., an epoxy molding compound or other molding compound), polyimide (PI) having the fillers 76 dispersed therein, a phenolic compound or material having the fillers 76 dispersed therein, a polymer material with silicone (i.e., the fillers 76) dispersed therein, or a combination thereof. In some arrangements, the distance D1 between the electronic components 30 and the carrier 20 is greater than three times a size D76 of the fillers 76, i.e., D1>3×D76.

The electrical contacts 81 may be disposed over a lower surface (or a bottom surface) of the carrier 10. In some arrangements, the electrical contacts 81 are disposed on and electrically connected to the pads 150 of the carrier 10. The electrical contacts 81 may be or include solder elements (e.g., solder bumps, solder balls, or the like). In some embodiments, the electrical contacts 81 include controlled collapse chip connection (C4) bumps, a ball grid array (BGA), or a land grid array (LGA). In some arrangements, the electrical contacts 81 (or the solder element) contact the encapsulant 74. In some arrangements, the electrical contact 81 (or the solder elements) is engaged with a portion of the encapsulant 74 and configured to provide a mold lock to increase a bonding strength between the encapsulant 74 and the carrier 10.

FIG. 1C is a top view of an electronic device 1C in accordance with some arrangements of the present disclosure. In some arrangements, FIG. 1A shows a cross-section along a line 1A-1A′ in FIG. 1C. Please be noted that some components/elements are omitted in FIG. 1C for clarity.

In some arrangements, the electronic device 1C includes a plurality of supports 50 and a plurality of supports 60. In some arrangements, the supports 50 are disposed at the central region R10c and the peripheral region R10p of the carrier 10. In some arrangements, at least two of the supports 50 are disposed at two corners of the carrier 10. The two corners may be opposite to each other. In some arrangements, at least four of the supports 50 are disposed at four corners of the carrier 10. In some arrangements, the supports 60 are disposed at the peripheral region R10p of the carrier 10.

FIG. 1D is a top view of an electronic device 1D in accordance with some arrangements of the present disclosure. In some arrangements, FIG. 1A shows a cross-section along a line 1A-1A′ in FIG. 1D. Please be noted that some components/elements are omitted in FIG. 1D for clarity.

In some arrangements, two portions of the supports 50 and 60 are disposed at two edges of the carrier 10, respectively. In some arrangements, some supports 50 and 60 are disposed at an edge of the carrier 10, and some supports 50 and 60 are disposed at an opposite edge of the carrier 10.

FIG. 1E is a top view of an electronic device 1E in accordance with some arrangements of the present disclosure. In some arrangements, FIG. 1A shows a cross-section along a line 1A-1A′ in FIG. 1E. Please be noted that some components/elements are omitted in FIG. 1E for clarity.

In some arrangements, the supports 50 and 60 are disposed at edges of the carrier 10. In some arrangements, some of the electronic components 30 are disposed at the peripheral region R10p of the carrier 10 and between the supports 50 and 60.

Simulation results are presented in Table 1 below to show the advantageous effects of the electronic devices in accordance with some embodiments of the present disclosure. Table 1 shows the influences of the supports on the warpage of the electronic device. Embodiment E1 refers to an electronic device including supports at four corners of the carrier 10, and Comparative embodiment C1 refers to an electronic device without any supports. “Maximum warpage” shows to the maximum value of a plurality of simulation results, and “Average warpage” shows the average value of the plurality of simulation results. It is apparent that the warpage is reduced after the supports are arranged in the electronic device.

TABLE 1

| | Maximum warpage (μm) | Average warpage (μm) |
|---|---|---|
| C1 | 103.62 | 81.12 |
| E1 | 103.54 | 78.92 |

When high-performance voltage regulating components (e.g., capacitors) are required to be arranged between stacked carriers to form a high-performance electronic device (or a high-performance IC modules), the height or the size of the capacitors are increased due to the increased performance they provide. In order to dispose the relatively large capacitors, the pitch or the size of the solder balls connecting the stacked carriers are enlarged so as to increase the spacing between the carriers for accommodating the relatively large capacitors; however, it also results in sacrificing the area available for placing the capacitors. As such, the increase in the pitch or the size of the solder balls results in a significant reduction in the number or the density of the capacitors disposed within the electronic device, making it unable to meet high-performance electrical requirements. For example, when the thickness of the capacitors increases from 0.36 mm to 0.55 mm, the size of the solder balls needs to be increased from 0.6 mm to 0.8 mm, and thereby the quantity of the capacitors per unit area decreases from 807 to 528, which is reduced significantly by 34%.

According to some arrangements of the present disclosure, at least one support 50 is disposed at a specific region on the carrier 10 to increase the spacing between the carriers 10 and 20. Therefore, a greater number of the electronic components 30 (or the capacitors) can be arranged between the carriers 10 and 20 within the electronic device 1, and thus a high-performance electronic device (or a high-performance IC module) can be accomplished.

In addition, according to some arrangements of the present disclosure, the aspect ratio of the supports 50 and 60 is greater than the aspect ratio of a solder ball (e.g., the conductive element 40). Therefore, the relatively thin supports 50 and 60 can enlarge the spacing between the carriers 10 and 20, e.g., by about 1.5 times, without occupying large device areas. Therefore, the quantity of the electronic components 30 per unit area of the carrier 10 can be increased significantly, e.g., by about 20%, making it capable of meeting high-performance electrical requirements.

Moreover, according to some arrangements of the present disclosure, the aspect ratio of the supports 50 and 60 is equal to or less than 2 or 1.4. With the above design, the aspect ratio of the supports 50 and 60 is not too high, which would otherwise make the supports 50 and 60 too tall or too thin and thus prone to tipping over, bending, toppling over, or cracking.

In addition, according to some arrangements of the present disclosure, the support 50 is free of a solder material and is formed of or includes a metal material, a ceramic material, or a plastic material. As such, while solder balls may melt by a reflow operation and form a substantially ball shape having a relatively small aspect ratio, the height or the aspect ratio of the support 50 can be controlled and adjusted to enlarge the spacing between the carriers 10 and 20 without occupying large device areas. Therefore, the quantity of the electronic components 30 per unit area of the carrier 10 can be increased significantly, making it capable of meeting high-performance electrical requirements. Furthermore, the support 50 includes a metal material or a ceramic material having a relatively high adhesion with the encapsulant 74, and thus delamination can be prevented effectively.

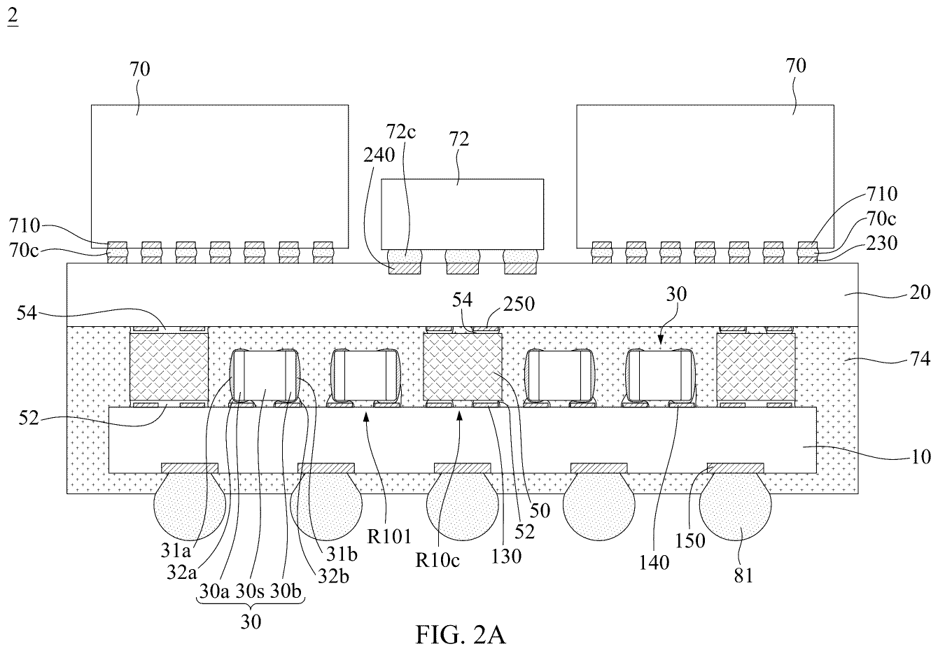

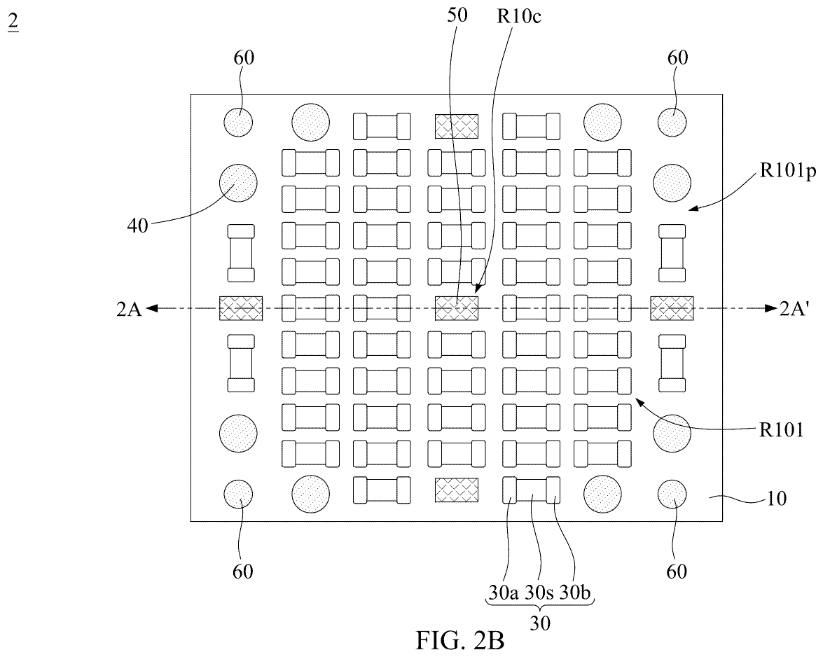

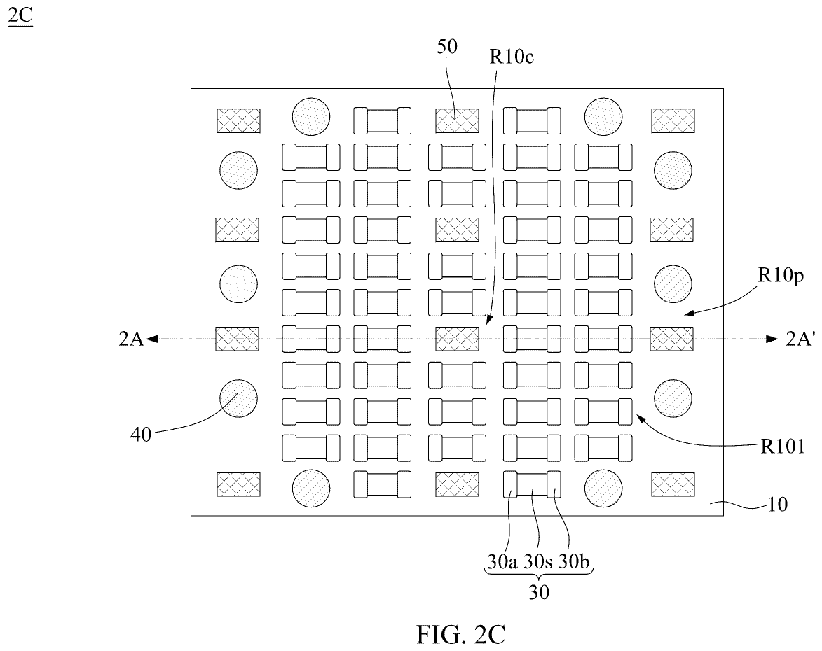

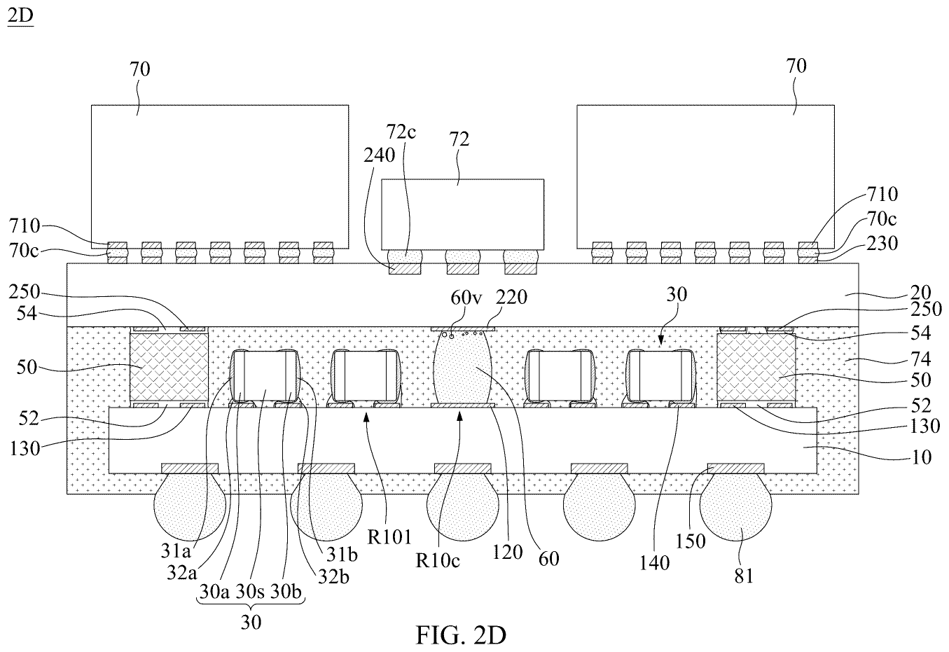

FIG. 2A is a cross-section of an electronic device 2 in accordance with some arrangements of the present disclosure. FIG. 2B is a top view of an electronic device 2 in accordance with some arrangements of the present disclosure. In some arrangements, FIG. 2A is a cross-section along a line 2A-2A′ in FIG. 2B. Please be noted that some components/elements are omitted in FIG. 2B for clarity. The electronic device 2 shown in FIGS. 2A-2B is similar to the electronic device 1 in FIGS. 1A-1B, and the differences therebetween are described as follows.

In some arrangements, at least one of the solder elements 52 contacts two pads 130 of the carrier 10. In some arrangements, the carrier 20 further includes pads 250 (or conductive pads), and the electronic device 2 further includes solder elements 54 connecting the supports 50 to the pads 250. In some arrangements, at least one of the solder elements 54 includes two portions that are spaced apart from each other and contacting the pads 250, respectively. In some arrangements, at least one of the solder elements 54 contacts two pads 250 of the carrier 20. In some arrangements, the pads 250 are dummy pads without electrical connection functions.

In some arrangements, the pads 130 and 250 are dummy pads without electrical connection functions. In some arrangements, the support 50 is configured to be free of electrical connection functions. In some arrangements, the support 50 is configured to provide electrical connection functions. In some arrangements, the support 50 is configured to transmit an electrical signal (e.g., a power signal, a control signal, or other electrical signals) through the pads 130 and 250.

Referring to FIG. 2B, in some arrangements, the supports 60 are at the peripheral region R10p of the carrier 10. In some arrangements, at least two of the supports 60 are disposed at two corners of the carrier 10. The two corners may be opposite to each other.

FIG. 2C is a top view of an electronic device 2C in accordance with some arrangements of the present disclosure. In some arrangements, FIG. 2A shows a cross-section along a line 2A-2A′ in FIG. 2C. Please be noted that some components/elements are omitted in FIG. 2C for clarity.

In some arrangements, the supports 50 are at the central region R10c and the peripheral region R10p of the carrier 10.

FIG. 2D is a cross-section of an electronic device 2D in accordance with some arrangements of the present disclosure. The electronic device 2D shown in FIG. 2D is similar to the electronic device 1 in FIGS. 1A-1B or the electronic device 2 in FIGS. 2A-2B, and the differences therebetween are described as follows.

In some arrangements, the electronic device 2 includes a support 60 at the central region R10c of the carrier 10. In some arrangements, FIG. 2D shows a cross-section along a line 2A-2A′ in FIG. 2B and/or in FIG. 2C, except that the support 50 at the central region R10c shown in FIG. 2B and FIG. 2C is replaced by a support 60.

According to some arrangements of the present disclosure, the supports 50 are connected to both of the carriers 10 and 20 through solder elements. Therefore, the solder elements can further improve the adhesion between the supports 50 and the carriers 10 and 20, and the solder elements can further enlarge the spacing between the carriers 10 and 20. As such, a high-performance electronic device (or a high-performance IC module) can be accomplished, and the reliability of the electronic device can be improved.

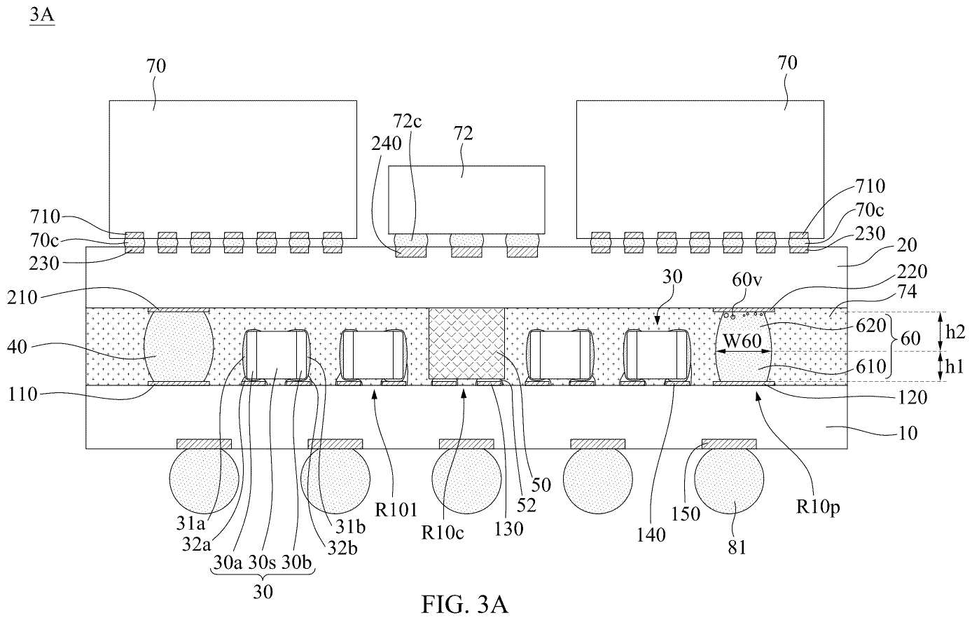

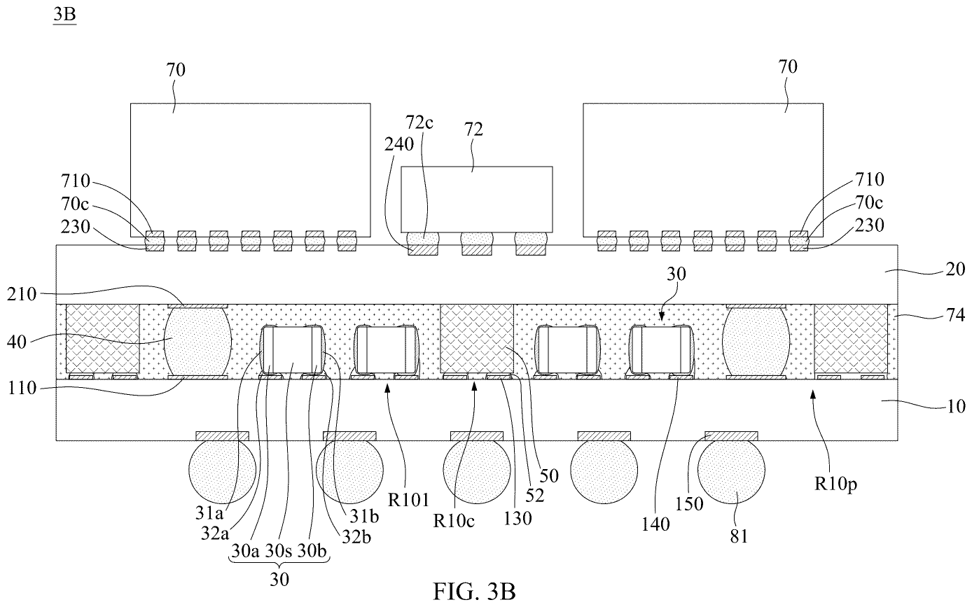

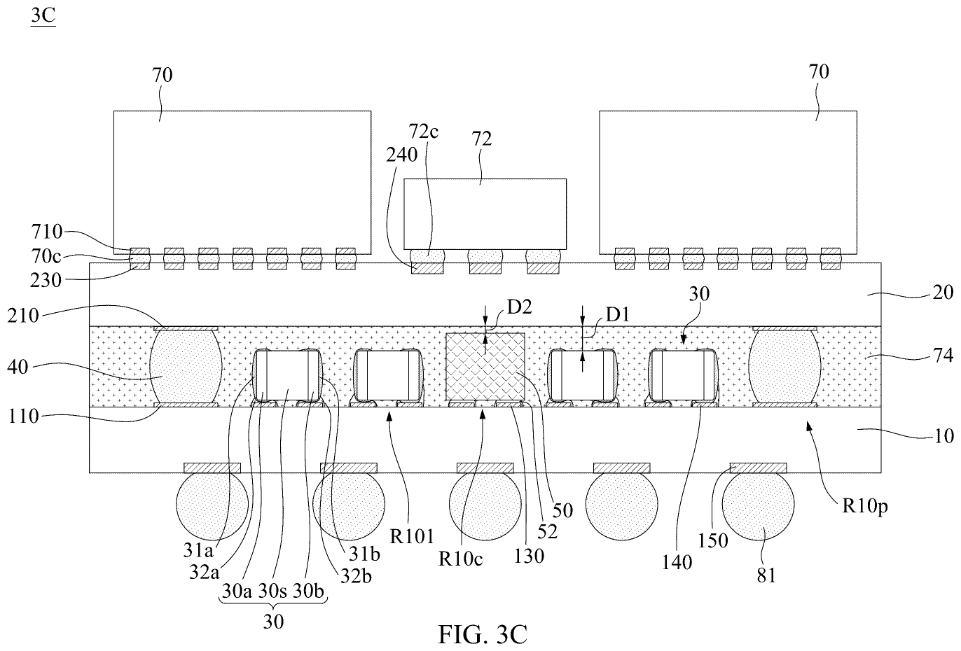

FIG. 3A is a cross-section of an electronic device 3A in accordance with some arrangements of the present disclosure. In some arrangements, FIG. 3A shows a cross-section along a line 1A-1A′ in FIGS. 1B, 1C, 1D, and 1E. The electronic device 3A shown in FIG. 3A is similar to the electronic device 1 in FIG. 1A, and the differences therebetween are described as follows.

In some arrangements, the encapsulant 74 is between the carrier 10 and the carrier 20. In some arrangements, at least an edge of the encapsulant 74 substantially aligns with at least an edge of the carrier 10.

FIG. 3B is a cross-section of an electronic device 3B in accordance with some arrangements of the present disclosure. The electronic device 3B shown in FIG. 3B is similar to the electronic device 3A in FIG. 3A, and the differences therebetween are described as follows.

In some arrangements, some of the supports 50 and the conductive elements 40 are at the peripheral region R10p of the carrier 10, and at least one of the supports 50 is at the central region R10c of the carrier 10.

FIG. 3C is a cross-section of an electronic device 3C in accordance with some arrangements of the present disclosure. The electronic device 3C shown in FIG. 3C is similar to the electronic device 3A in FIG. 3A, and the differences therebetween are described as follows.

In some arrangements, at least one of the conductive elements 40 is closer to the carrier 20 than the support 50 is. In some arrangements, the support 50 is spaced apart from the carrier 20 by a distance D2. In some arrangements, the distance D2 between the support 50 and the carrier 20 is less than the distance D1 between the electronic components 30 and the carrier 20.

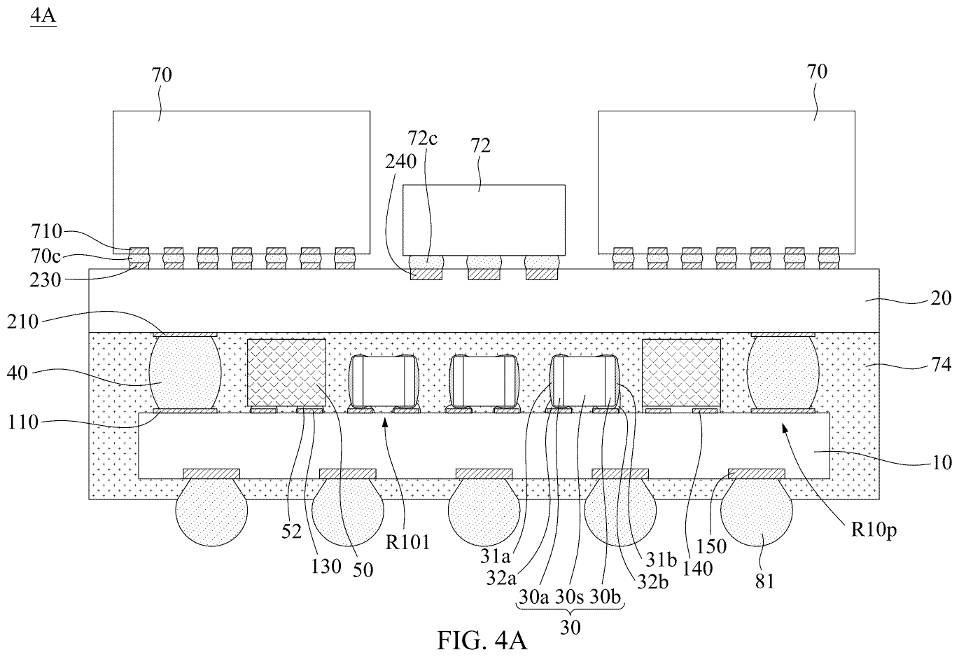

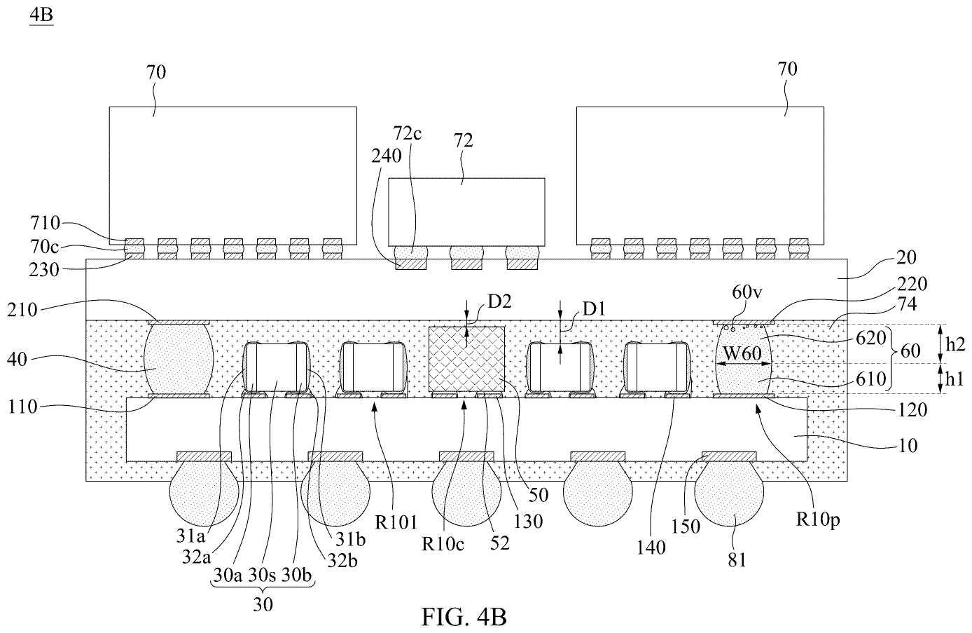

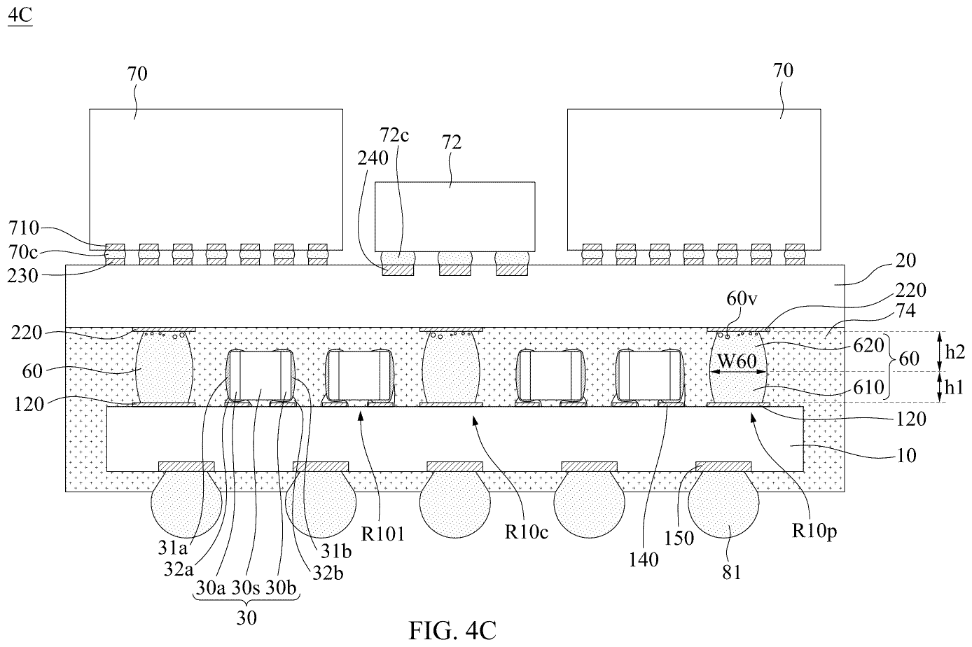

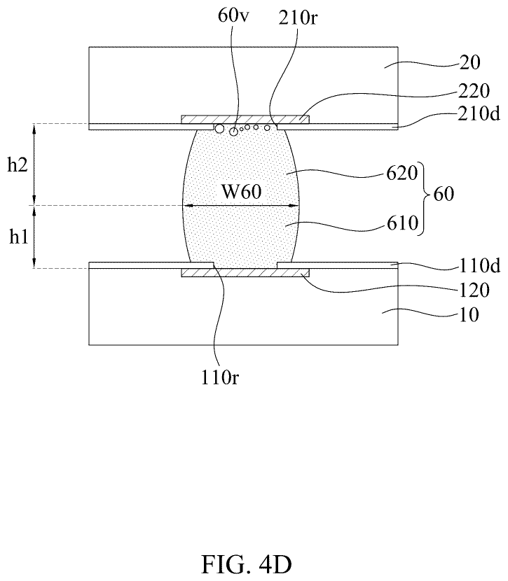

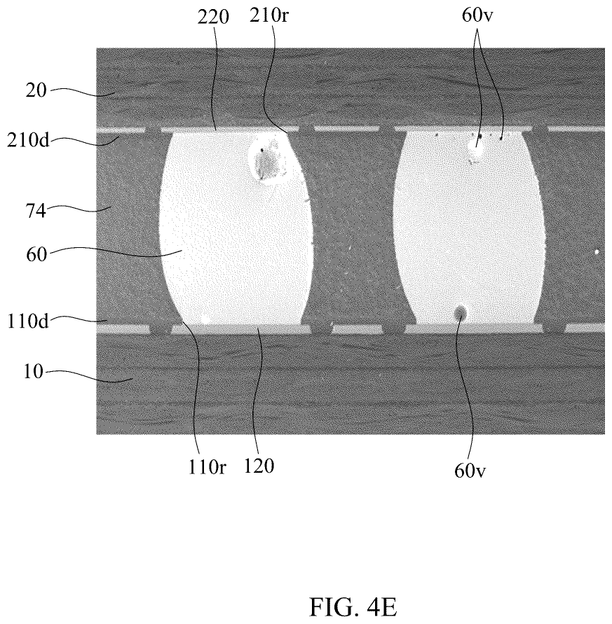

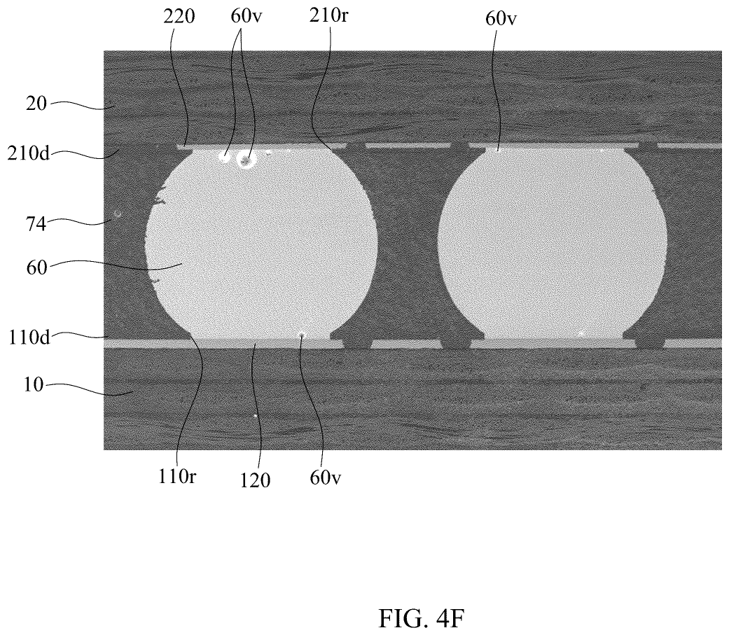

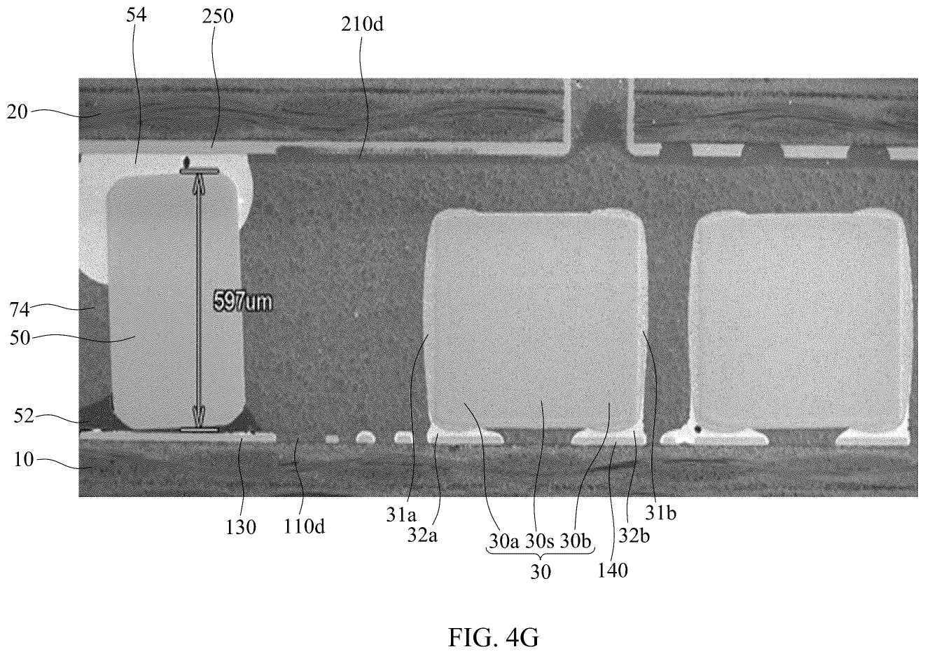

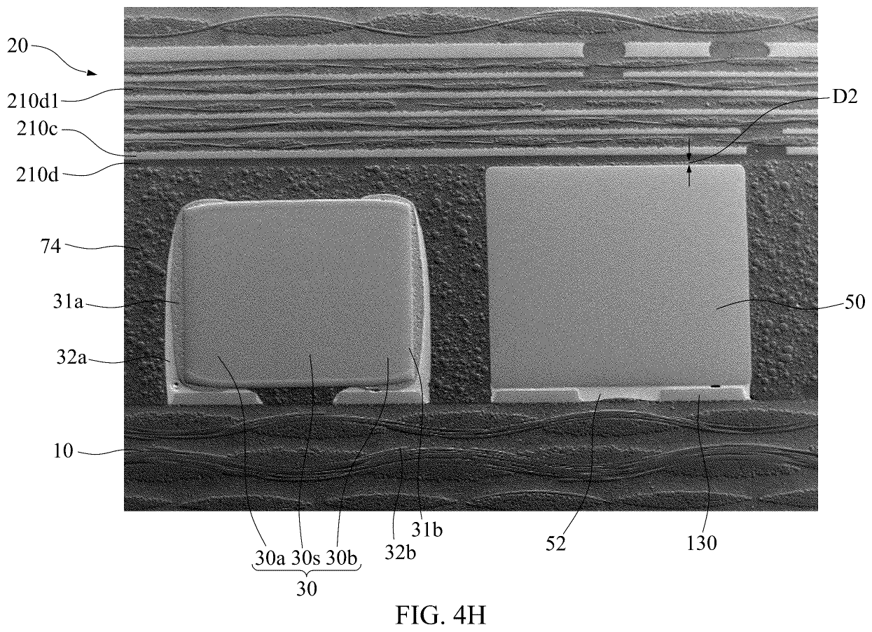

FIG. 4A is a cross-section of an electronic device 4A in accordance with some arrangements of the present disclosure. The electronic device 4A shown in FIG. 4A is similar to the electronic device 1 in FIG. 1A, and the differences therebetween are described as follows.

In some arrangements, the electronic components 30 are disposed between the supports 50. In some arrangements, the supports 50 and the conductive elements 40 are disposed at the peripheral region R10p of the carrier 10.

FIG. 4B is a cross-section of an electronic device 4B in accordance with some arrangements of the present disclosure. In some arrangements, FIG. 4B shows a cross-section along a line 1A-1A′ in FIGS. 1B, 1C, 1D, and 1E. The electronic device 4B shown in FIG. 4B is similar to the electronic device 1 in FIG. 1A, and the differences therebetween are described as follows.

In some arrangements, the support 60 contacts the pad 220 of the carrier 20, and the support 50 is spaced apart from the carrier 20. In some arrangements, the support 50 is spaced apart from the carrier 20 by a distance D2. In some arrangements, the distance D2 between the support 50 and the carrier 20 is less than the distance D1 between the electronic components 30 and the carrier 20.

FIG. 4C is a cross-section of an electronic device 4C in accordance with some arrangements of the present disclosure. In some arrangements, FIG. 4C shows a cross-section along a line 1A-1A′ in FIGS. 1B, 1C, 1D, and 1E with some or all of the supports 50 replaced by the supports 60. The electronic device 4C shown in FIG. 4C is similar to the electronic device 1 in FIG. 1A, and the differences therebetween are described as follows.

In some arrangements, the supports 60 are disposed between the carrier 10 and the carrier 20. In some arrangements, the supports 60 are at the central region R10c and the peripheral region R10p of the carrier 10.

FIG. 4D is a cross-section of a portion of an electronic device in accordance with some arrangements of the present disclosure. In some arrangements, FIG. 4D shows a cross-section of a portion of the electronic devices 1, 2, 3A, 4B, and/or 4C. In some arrangements, FIG. 4D is a portion including the support 60.

In some arrangements, the carrier 10 includes a pad 120 connected to the support 60 and a dielectric layer 110d defining a cavity 110r for exposing the pad 120. In some arrangements, the carrier 20 includes a pad 220 connected to the support 60 and a dielectric layer 210d defining a cavity 210r for exposing the pad 220. In some arrangements, a first portion of the voids 60v is within the cavity 210r, and a second portion of the voids 60v is outside of the cavity 210r. In some arrangements, the dielectric layers 110d and 220d may include a solder resist, a solder mask, or the like.

FIG. 4E is a cross-section of a portion of an electronic device in accordance with some arrangements of the present disclosure. In some arrangements, FIG. 4E shows a cross-section of a portion of the electronic devices 1, 2, 3A, 4B, and/or 4C with a minor modification that two supports 60 are disposed adjacent to each other. In some arrangements, FIG. 4E is a portion including the support 60.

In some arrangements, the support 60 includes voids 60v at a region close to the pad 120 and a region close to the pad 220. In some arrangements, at least two of the voids 60v have different sizes (or diameters). In some arrangements, the support 60 has an asymmetrical structure. In some arrangements, the support 60 has a cross-sectional profile that is asymmetrical relative to a longitudinal axis (e.g., an axis substantially parallel to a normal line to an upper surface of the pad 120).

FIG. 4F is a cross-section of a portion of an electronic device in accordance with some arrangements of the present disclosure. FIG. 4F shows a cross-section of a portion of the electronic devices 1, 2, 3A, 4B, and/or 4C with a minor modification that two supports 60 are disposed adjacent to each other. In some arrangements, FIG. 4F is a portion including the support 60.

In some arrangements, the support 60 has a substantially symmetrical structure. In some arrangements, the support 60 has a substantially ball-shaped cross-sectional profile.

FIG. 4G is a cross-section of a portion of an electronic device in accordance with some arrangements of the present disclosure. FIG. 4G shows a cross-section of a portion of the electronic devices 2 and/or 2D. In some arrangements, FIG. 4G is a portion including the electronic components 30 and the support 50.

In some arrangements, the support 50 is tilted with respect to an upper surface of the pad 130. In some arrangements, the support 50 is connected to one pad 130 through the solder element 52 and one pad 250 through the solder element 54. In some arrangements, the solder element 52 extends over lateral surfaces of the support 50 by different distances. In some arrangements, the solder element 54 extends over lateral surfaces of the support 50 by different distances. In some arrangements, the solder elements 52 and 54 have different thicknesses.

FIG. 4H is a cross-section of a portion of an electronic device in accordance with some arrangements of the present disclosure. FIG. 4G shows a cross-section of a portion of the electronic devices 3C, 4A and/or 4B. In some arrangements, FIG. 4G is a portion including the electronic components 30 and the support 50.

In some arrangements, the carrier 20 includes a plurality of conductive layers 210c (or conductive traces or conductive pads), a dielectric structure 210d1 encapsulating the conductive traces 210c, and a dielectric layer 210d covering a bottommost conductive trace 210c and contacting the dielectric structure 210d1. The dielectric structure 210d1 may include a plurality of dielectric layers disposed between the conductive layers 210c. The dielectric structure 210d1 and the dielectric layer 210d may include different materials. In some arrangements, the support 50 is spaced apart from the dielectric layer 210a of the carrier 20 by a distance D2.

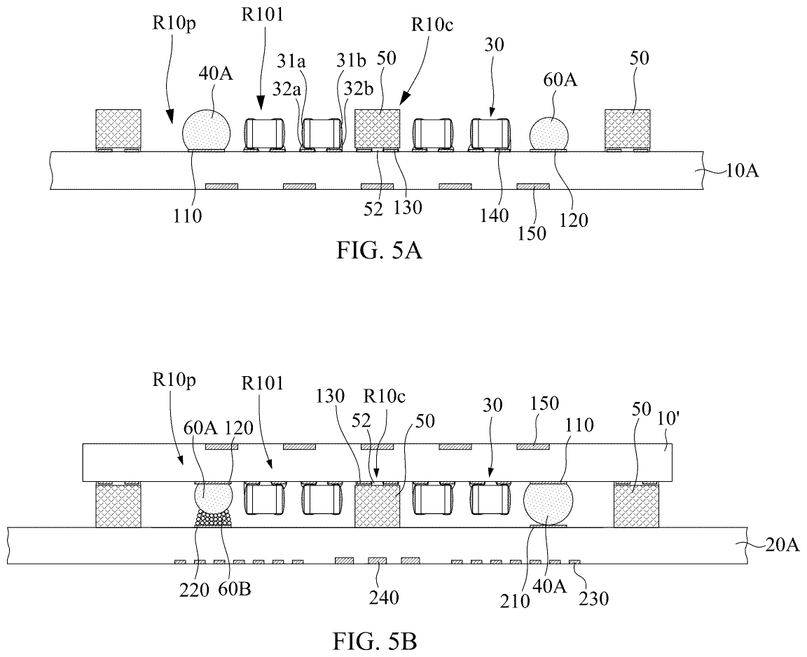

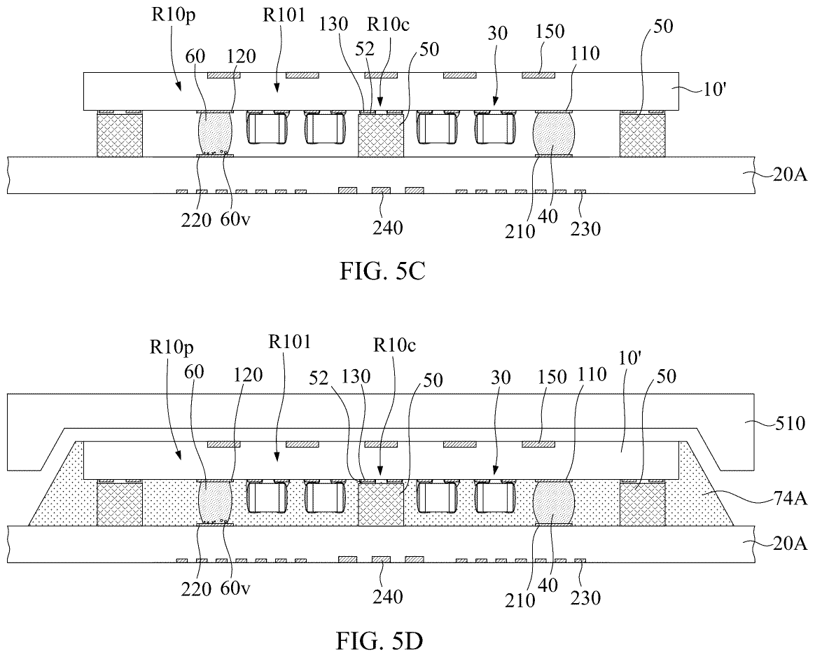

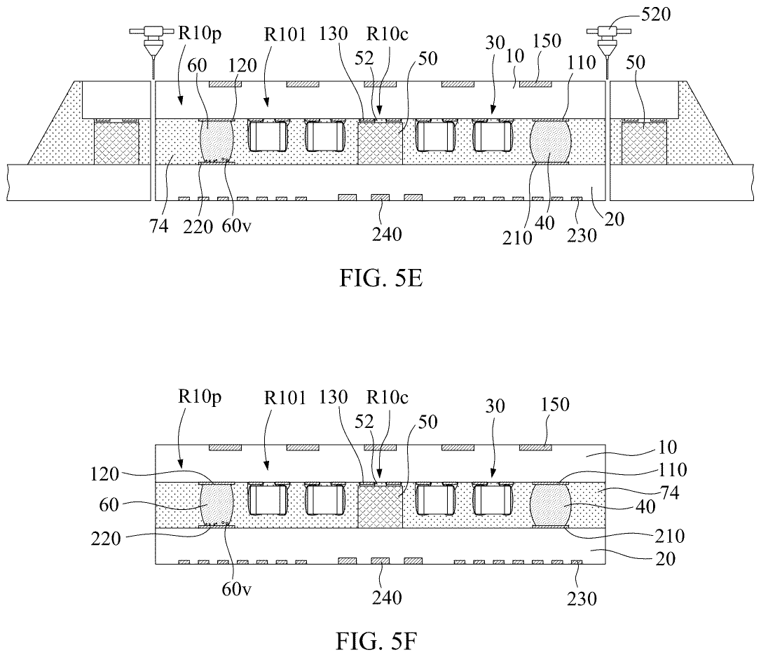

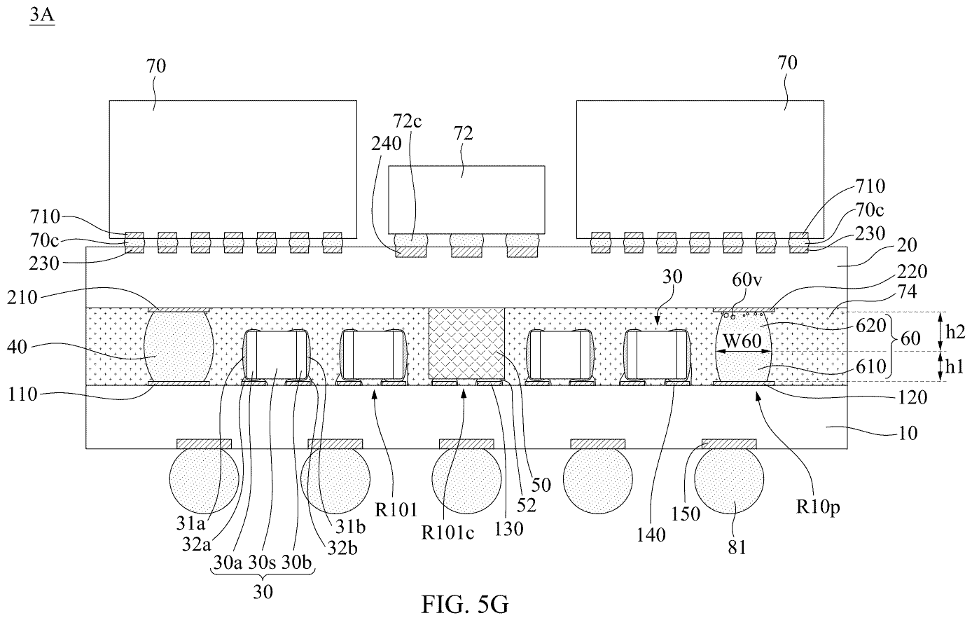

FIG. 5A, FIG. 5B, FIG. 5C, FIG. 5D, FIG. 5E, FIG. 5F, and FIG. 5G illustrate various stages of an exemplary method for manufacturing an electronic device 3A in accordance with some embodiments of the present disclosure.

Referring to FIG. 5A, a carrier strip 10A including pads 110, 120, 130, 140, and 150 may be provided, supports 50 may be disposed on the pads 130 of the carrier strip 10A, electronic components 30 may be disposed on the pads 140 of the carrier strip 10A, and solder balls 40A and 60A may be disposed on the pads 110 and 120, respectively. In some arrangements, a size or a width of the solder ball 60A is less than a size or a width of the solder ball 40A. In some arrangements, the supports 50 and the electronic components 30 are disposed on or connected to the carrier strip 10A by a surface mount technology (SMT) process. In some arrangements, the carrier strip 10A is or includes a strip-form printed circuit board (PCB). In some arrangements, the supports 50 are disposed on at least two or more corners of the carrier strip 10A.

Referring to FIG. 5B, the carrier strip 10A may be singulated to form a plurality of carriers 10′, a carrier strip 20A including pads 210, 220, 230, and 240 may be provided, and the singulated carrier 10′ may be mounted to the carrier strip 20A by a SMT process. In some arrangements, one or more solder pastes 60B may be disposed or printed on one or more pads 220 of the carrier strip 20A, and one or more solder balls 60A may be guided to contact or to be close to the one or more solder pastes 60B. In some arrangements, one or more solder balls 40A may be guided to contact or to be close to one or more pads 210 of the carrier strip 20A.

Referring to FIG. 5C, a reflow operation may be perform to form one or more supports 60 and one or more conductive elements 40. In some arrangements, the solder ball 40A melts to form the conductive element 40 that connects to the pad 110 and the pad 210. In some arrangements, the solder ball 60A and the solder paste 60B melt to form the support 60 that connects to the pad 120 and the pad 220. In some arrangements, the solder paste 60B include a plurality of solder beads mixed in a binder material, voids 60v may form when the solder beads melt by the reflow operation. The solder ball 60A and the solder paste 60B may melt and approach to each other to form a relatively thin solder structure, i.e., the support 60, compared to the conductive element 40. In some arrangements, because the support 60 includes a portion formed of the solder paste 60B and a portion formed of the solder ball 60A, the support 60 has a maximum width not located at the midpoint of its height. In some arrangements, the maximum width of the support 60 is closer to the carrier 10 than to the carrier 20.

According to some arrangements of the present disclosure, the solder paste 60B is disposed or printed on the carrier 10 and bonded to the solder ball 60A to form a relatively thin support 60 after a reflow operation. With the above process, the melted solder paste 60B may serve as an elevated structure to add up the overall thickness or height of the as-formed support 60, and the maximum width of the as-formed support 60 may be defined by the width of the relatively small solder ball 60A and thus smaller than the conductive element 40 formed of the solder ball 40A. Therefore, the conductive elements 40 and the supports 60 may be formed by the same solder ball attaching operation, the electrical connection features (e.g., the conductive elements 40) and the supporting and elevating features (e.g., the supports 60) can be formed by the same operation accordingly, and thus the manufacturing process can be simplified.

Referring to FIG. 5D, an encapsulant 74 is formed between the carrier 10′ and the carrier strip 20A by a molding process. In some arrangements, a mold 510 may be applied over the carrier 10′ and apply a force over the carrier 10′ and the carrier strip 20A when shaping the encapsulant 74. In some arrangements, the supports 50 and 60 may serve to withstand the force by the mold 510 on the conductive elements 40 so as to reduce deformation of the carrier 10′ and the carrier strip 20A caused by the mold 510.

Referring to FIG. 5E, a singulation operation may be performed on the structure illustrated in FIG. 5D. In some arrangements, the singulation operation includes cutting the structure to remove corner portions of the structure by laser from a laser equipment 520. In some arrangements, the supports 50 at corners are removed by the singulation operation.

Referring to FIG. 5F, the cut-off portions including the supports 50 at corners may be removed, and singulation structures including singulated carriers 10 and 20 may be formed.

According to some arrangements of the present disclosure, the supports 50 are disposed on non-functional regions (e.g., the corners of the carrier 10) during the early stage of the process can further provide support to withstand the force by the mold 510, and the supports 50 at the non-functional regions (e.g., the corners of the carrier 10) are removed by the singulation operation can reduce the device size.

Referring to FIG. 5G, electrical contacts 81 may be formed on the pads 150 of the carrier 10, electronic components 70 may be connected to the pads 230 of the carrier 20, and a connector 72 may be connected to the pads 240 of the carrier 20. As such, the electronic device 3A illustrated in FIG. 3A may be formed.

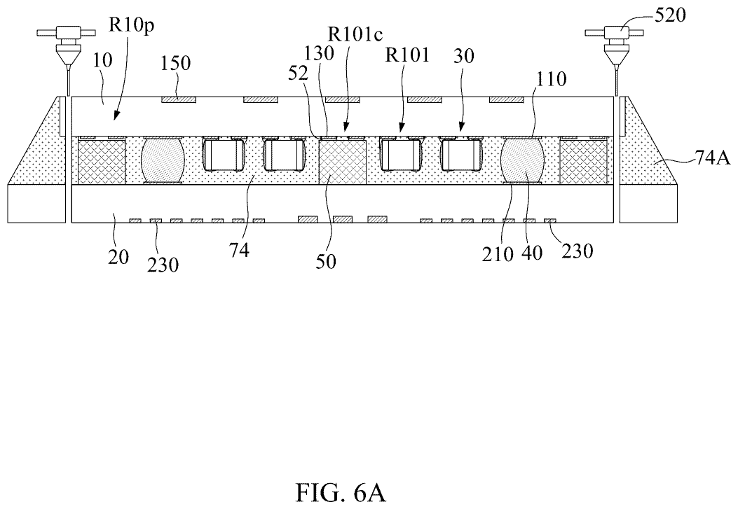

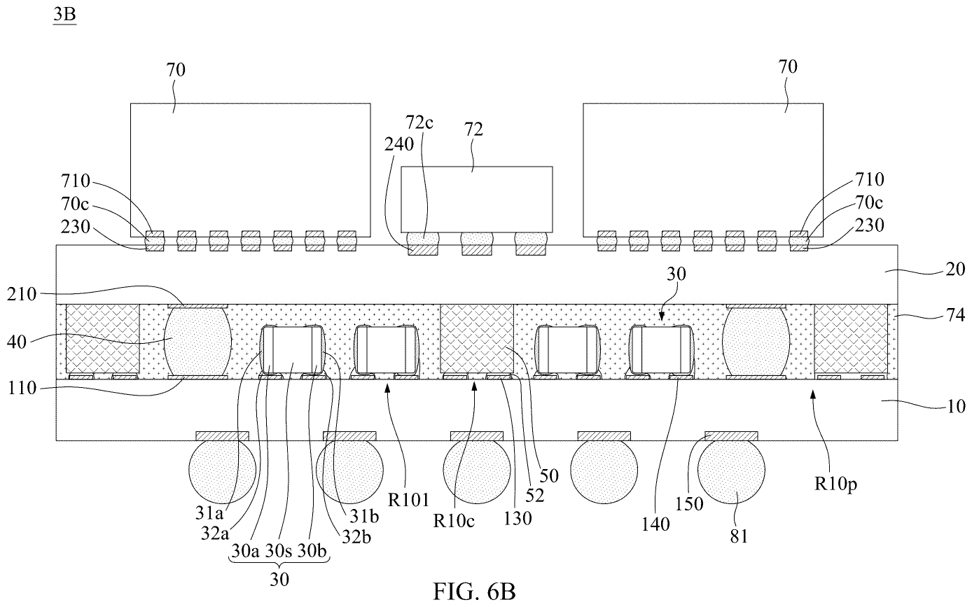

FIG. 6A and FIG. 6B illustrate various stages of an exemplary method for manufacturing an electronic device 3B in accordance with some embodiments of the present disclosure.

Referring to FIG. 6A, operations similar to those illustrated in FIGS. 5A-5D may be performed, and a singulation operation may be performed on the structure illustrated in FIG. 5D. In some arrangements, the singulation operation includes cutting the structure to remove corner portions of the structure by laser from a laser equipment 520. In some arrangements, the supports 50 at corners are not removed by the singulation operation. In some arrangements, the cut-off portions including portions of the encapsulant 74 and the carrier 10′ at corners may be removed, and singulation structures including singulated carriers 10 and 20 may be formed.

Referring to FIG. 6B, electrical contacts 81 may be formed on the pads 150 of the carrier 10, electronic components 70 may be connected to the pads 230 of the carrier 20, and a connector 72 may be connected to the pads 240 of the carrier 20. As such, the electronic device 3B illustrated in FIG. 3B may be formed.

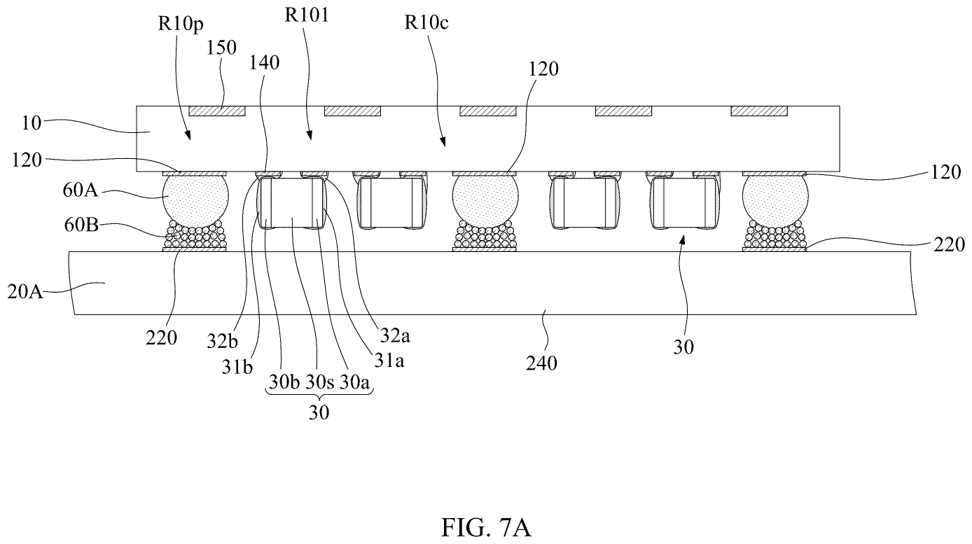

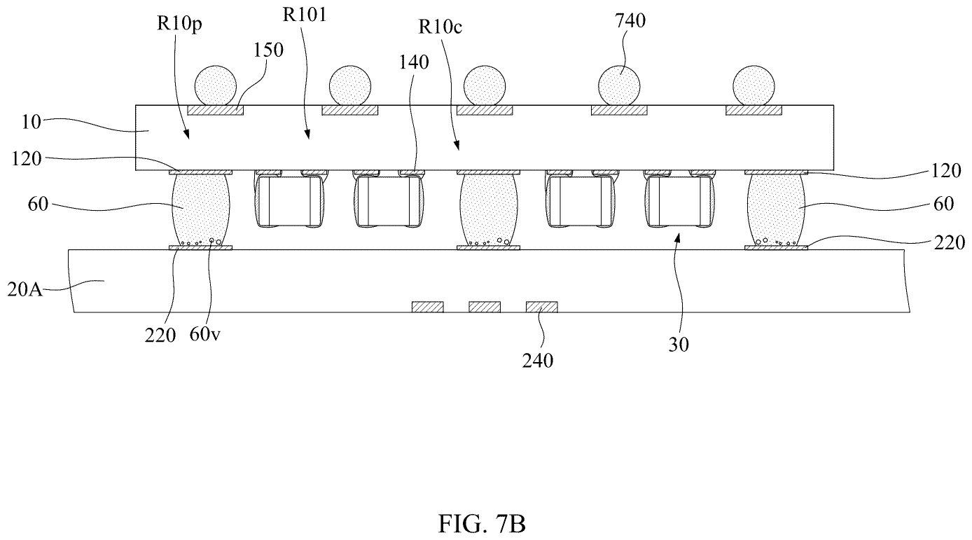

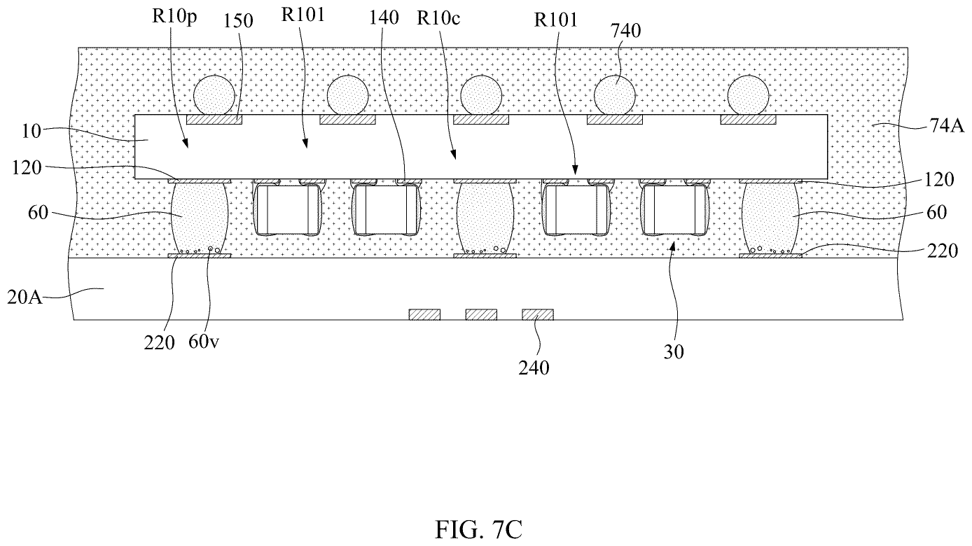

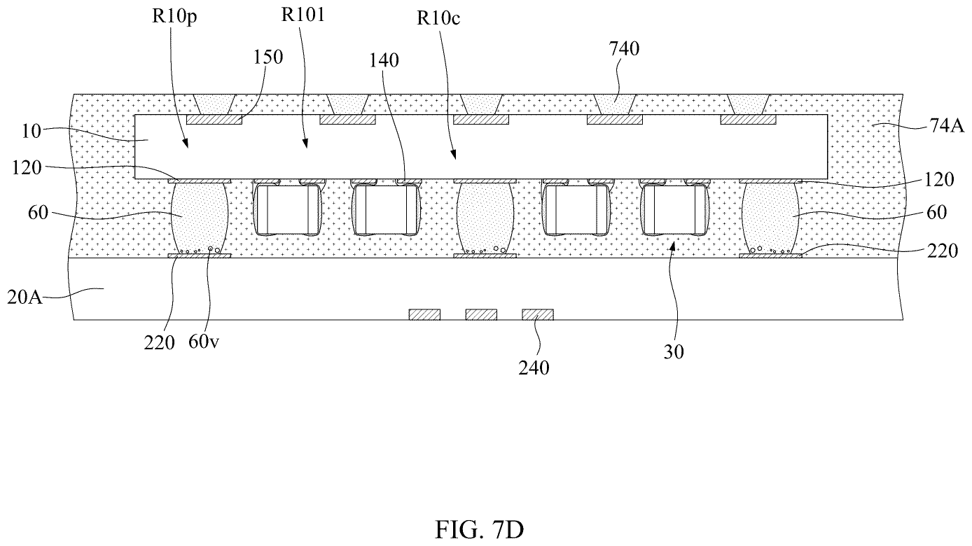

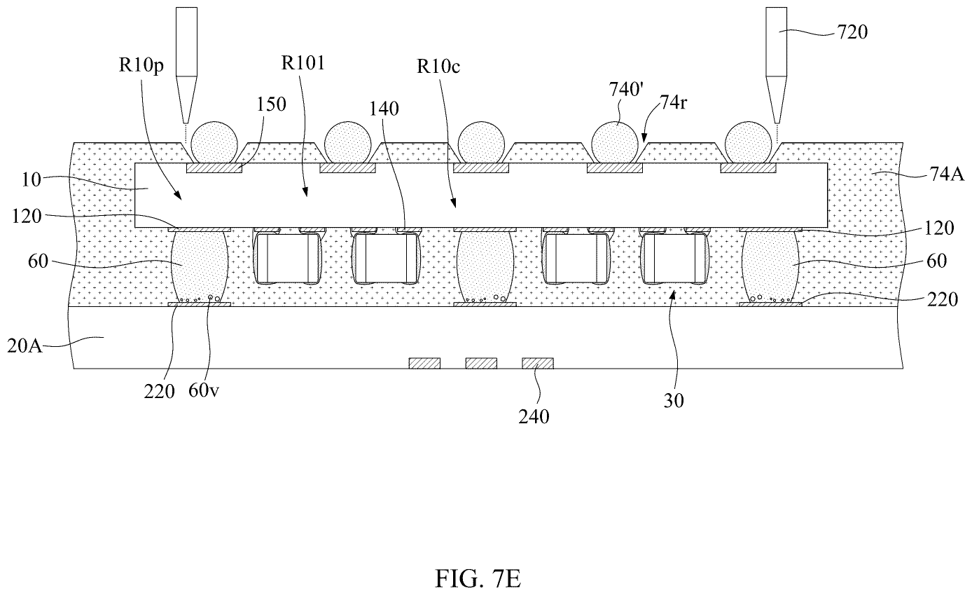

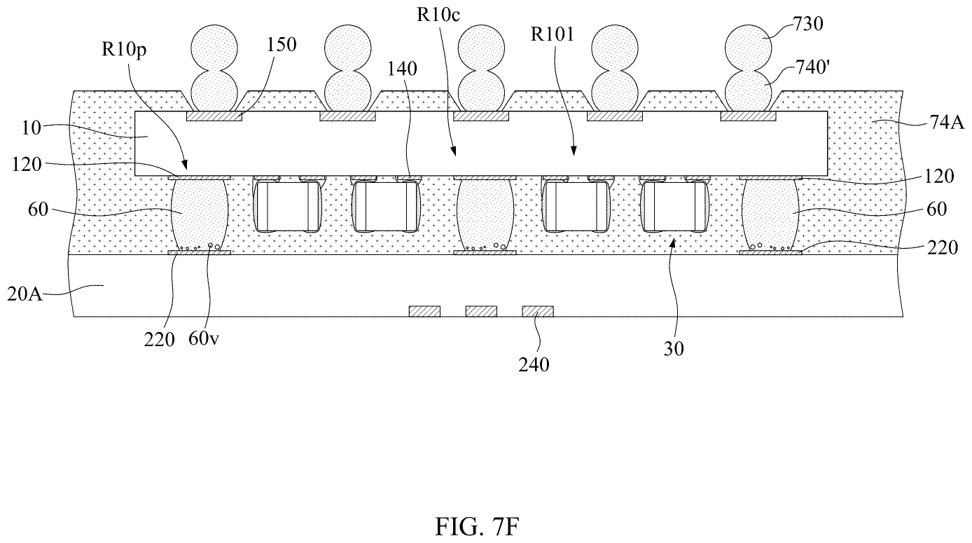

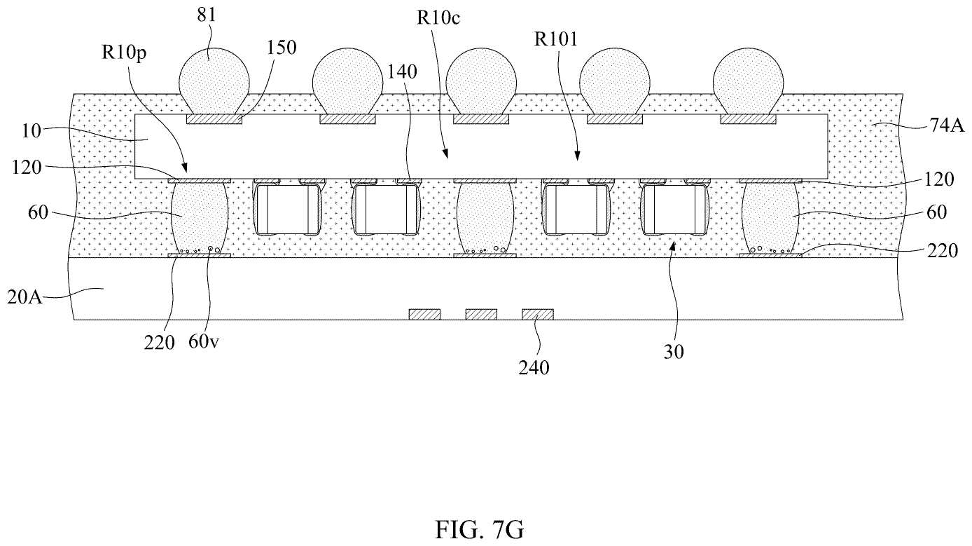

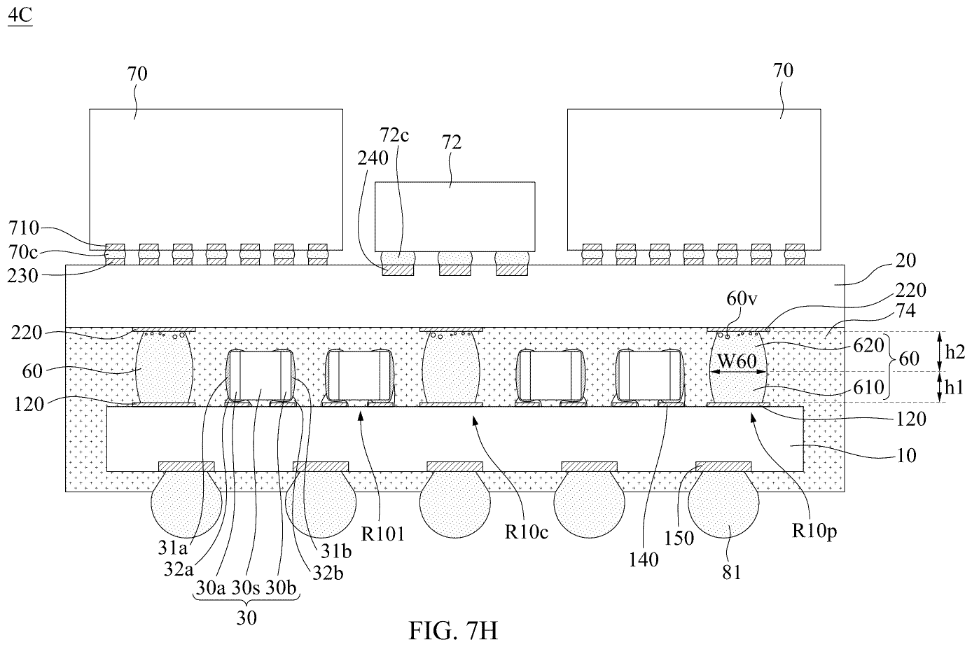

FIG. 7A, FIG. 7B, FIG. 7C, FIG. 7D, FIG. 7E, FIG. 7F, FIG. 7G, and FIG. 7H illustrate various stages of an exemplary method for manufacturing an electronic device 4C in accordance with some embodiments of the present disclosure.

Referring to FIG. 7A, a carrier 10 including pads 120, 130, 140, and 150 may be provided, electronic components 30 may be disposed on the pads 140 of the carrier 10, and solder balls 60A may be disposed on the pads 120, a carrier strip 20A including pads 220, 230, and 240 may be provided, solder pastes 60B may be disposed or printed on the pads 220, and the carrier 10 may be mounted to the carrier strip 20A.

In some arrangements, the solder balls 60A are disposed on the central region R10c and the peripheral region R10p of the carrier 10, and the electronic components 30 are disposed on the region R101 of the carrier 10. In some arrangements, the solder balls 60A and the electronic components 30 are mounted on a carrier strip under a temperature from about 235° C. to about 245° C., and then the carrier strip is singulated to form a plurality of carriers 10 each with the mounted solder balls 60A and the electronic components 30. In some arrangements, the solder balls 60A are guided to contact or to be close to the solder pastes 60B.

Referring to FIG. 7B, a reflow operation may be perform to form supports 60. In some arrangements, each of the solder balls 60A and each of the solder pastes 60B melt to form one of the supports 60 that connect to the pads 120 and the pads 220. In some arrangements, the solder paste 60B include a plurality of solder beads mixed in a binder material, voids 60v may form when the solder beads melt by the reflow operation. The solder ball 60A and the solder paste 60B may melt and approach to each other to form a relatively thin solder structure, i.e., the support 60.

Referring to FIG. 7C, solder balls 740 may be formed the pads 150, and an encapsulant 74A may be formed to cover the carrier 10, the electronic components 30, the supports 60, and the solder balls 740. The encapsulant 74A may be formed by an over mold process.

Referring to FIG. 7D, a portion of the encapsulant 74A may be removed to expose the solder balls 740. In some arrangements, a grinding operation may be performed to partially remove the encapsulant 74A and the solder balls 740 to exposed substantially flat surfaces of the solder balls 740.

Referring to FIG. 7E, portions of the encapsulant 74A may be further removed to form recesses 74r defined by a plurality of sidewalls, and the sidewalls are spaced apart from the as-formed solder balls 740′. In some arrangements, a laser may be applied by a laser equipment 720 to partially remove the encapsulant 74A and also heat the remained solder balls 740. In some arrangements, the remained solder balls 740 may melt by the laser energy and turn into solder balls 740′ having a substantially ball shape.

Referring to FIG. 7F, solder balls 730 may be disposed on the solder balls 740′.

Referring to FIG. 7G, a reflow operation may be performed to melt the solder balls 730 and 740′ to form electrical contacts 81 that are filled in the recesses 74r of the encapsulant 74A.

Referring to FIG. 7H, a singulation operation may be performed on the structure illustrated in FIG. 7G to form singulated structures including singulated encapsulants 74 and carriers 20, electronic components 70 may be connected to the pads 230 of the carrier 20, and a connector 72 may be connected to the pads 240 of the carrier 20. As such, the electronic device 4C illustrated in FIG. 4C may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a first carrier;
a second carrier stacked over the first carrier;
a first support disposed between the first carrier and the second carrier and at a central region of the first carrier; and
a plurality of voltage regulating components disposed between the first carrier and the second carrier, wherein at least one of the voltage regulating components is disposed outside of the central region of the first carrier.

2. The electronic device as claimed in claim 1, further comprising a second support disposed at a peripheral region of the first carrier.

3. The electronic device as claimed in claim 1, further comprising a plurality of second supports disposed at a peripheral region of the first carrier, wherein at least two of the second supports are disposed at two corners of the first carrier.

4. The electronic device as claimed in claim 3, wherein the two corners are opposite to each other.

5. The electronic device as claimed in claim 1, further comprising a second support and a third support disposed at two edges of the first carrier, respectively.

6. The electronic device as claimed in claim 1, further comprising a plurality of conductive elements connecting the first carrier to the second carrier and configured to transmit a power signal.

7. The electronic device as claimed in claim 6, wherein at least one of the conductive elements is closer to the second carrier than the first support is.

8. The electronic device as claimed in claim 1, wherein the first support is closer to the second carrier than the voltage regulating components are.

9. The electronic device as claimed in claim 8, further comprising a plurality of second supports disposed between the first carrier and the second carrier, and the first support and the second supports are all closer to the second carrier than the voltage regulating components are.

10. An electronic device, comprising:
a first carrier;
a second carrier stacked over the first carrier;
a plurality of conductive elements configured to transmit a power signal between the first carrier and the second carrier; and
at least one support disposed between the first carrier and a second carrier and configured to withstand a force on the conductive elements.

11. The electronic device as claimed in claim 10, wherein a rigidity of the at least one support is greater than a rigidity of the conductive elements.

12. The electronic device as claimed in claim 10, further comprising a voltage regulating component disposed between the first carrier and the second carrier and an encapsulant encapsulating the voltage regulating component and comprising a plurality of fillers, wherein a distance between the voltage regulating component and the second carrier is greater than three times a size of the fillers.

13. The electronic device as claimed in claim 12, wherein the voltage regulating component and the at least one support are connected to the first carrier through surface mount connection.

14. The electronic device as claimed in claim 11, wherein the at least one support comprises a first portion tapering toward the first carrier and a second portion tapering toward the second carrier, and a thickness of the first portion is less than a thickness of the second portion.

15. An electronic device, comprising:
a first carrier;
a second carrier stacked over the first carrier; and
a plurality of conductive elements disposed between the first carrier and the second carrier, wherein the conductive elements comprise a first conductive element configured to transmit a power signal and a second conductive element comprising voids.

16. The electronic device as claimed in claim 15, wherein the first conductive element and the second conductive element comprise at least a solder material, and the second conductive element is configured to transmit an electrical signal.

17. The electronic device as claimed in claim 15, wherein a width of the second conductive element is less than a width of the first conductive element.

18. The electronic device as claimed in claim 15, wherein the voids are closer to the second carrier than to the first carrier.

19. The electronic device as claimed in claim 15, wherein the second carrier comprises a pad connected to the second conductive element and a dielectric layer defining a cavity exposing the pad, and a first portion of the voids is within the cavity.

20. The electronic device as claimed in claim 19, wherein a second portion of the voids is outside of the cavity.
